(19) United States
(12) Patent Application Publication
(10) Pub. No.: US 2009/0302475 A1
(43) Pub. Date: Dec. 10, 2009

(54) SEMICONDUCTOR DEVICE AND MANUFACTURING METHOD THEREOF

(76) Inventors: Hayato Korogi, Hyogo (JP); Takeshi Harada, Shiga (JP); Akira Ueki, Osaka (JP)

Correspondence Address: MCDERMOTT WILL & EMERY LLP, 600 13TH STREET, NW, WASHINGTON, DC, 20005-3096, US

(21) Appl. No.: 12/539,836

(22) Filed: Aug. 12, 2009

Related U.S. Application Data
(63) Continuation of application No. PCT/JP2008/003788, filed on Dec. 16, 2008.

(30) Foreign Application Priority Data
Feb. 18, 2008 (JP) 2008-035685

(51) Int. Cl. H01L 23/532; H01L 21/768

(52) U.S. Cl. 257/761; 257/762; 257/763; 257/764; 257/750; 438/618; 257/E23.161; 257/E23.162; 257/E23.163; 257/E23.157; 257/E21.576

(57) ABSTRACT

A semiconductor device includes a first interlayer insulating film, and a plurality of first interconnects formed in the first interlayer insulating film. A void is selectively formed between adjacent ones of the plurality of first interconnects in the first interlayer insulating film, and a cap insulating film is formed in a region located over the void and between the interconnects. Respective widths of a lower end and an upper end of the void are substantially the same as a gap between the interconnects located adjacent to the void, and the lower end of the void is located lower than lower ends of the first interconnects located adjacent to the void.

### CROSS-REFERENCE TO RELATED APPLICATIONS

This is a continuation of Application PCT/JP2008/003788, filed on Dec. 16, 2008. This Non-provisional application claims priority under 35 U.S.C. 119(a) on Patent Application No. 2008-035685 filed in Japan on Feb. 18, 2008, the entire contents of which are hereby incorporated by reference.

### BACKGROUND

The present invention generally relates to semiconductor devices and manufacturing methods thereof. More particularly, the present invention relates to a semiconductor device having a multilayer interconnect structure, and a manufacturing method thereof.

With recent reduction in size of semiconductor devices, the gap between a plurality of elements of a semiconductor device, and the gap between interconnects connecting the elements to each other have been increasingly reduced. This has caused problems of increasing the capacitance between interconnects, and thus, reducing a signal transmission speed.

Thus, a method of reducing the capacitance between interconnects by forming a void (an air gap) between interconnects has been examined, as shown in Japanese Published Patent Application No. 2004-266244, U.S. Pat. No. 6,815,329, and U.S. Pat. No. 7,098,476.

As a first conventional example, a manufacturing method of interconnects, which is shown in Japanese Published Patent Application No. 2004-266244, will be described with reference to FIGS. 4A through 4E.

First, as shown in FIG. 4A, an interlayer insulating film 10 and a sacrificial film 11 are sequentially deposited over a semiconductor substrate (not shown).

Then, as shown in FIG. 4B, a plurality of grooves 11a for forming interconnects (hereinafter referred to as the “interconnect formation grooves 11a”) are formed in the sacrificial film 11 by a lithography method and a dry etching method. At this time, the dry etching conditions are adjusted so that the bottom surfaces of the interconnect formation grooves 11a reach the interlayer insulating film 10.

Then, as shown in FIG. 4C, conductive films 12, 13 are sequentially deposited on the sacrificial film 11, and in the interconnect formation grooves 11a. Then, the conductive films 12, 13, remaining on the sacrificial film 11, are removed by a chemical mechanical polishing (CMP) method to form interconnects 14.

Then, as shown in FIG. 4D, a porous film 15 is deposited on the sacrificial film 11 and the interconnects 14.

Then, as shown in FIG. 4E, the sacrificial film 11 is removed by heating or the like to form voids 16 between adjacent interconnects 14. A multilayer interconnect structure can be implemented by sequentially repeating the steps described above.

As a second conventional example, another manufacturing method of interconnects, which is shown in U.S. Pat. No. 6,815,329 and U.S. Pat. No. 7,098,476, will be described below with reference to FIGS. 5A through 5E.

First, as shown in FIG. 5A, an interlayer insulating film 21 is deposited on a semiconductor substrate 20. Then, a hard mask pattern 22 for forming vias (hereinafter referred to as the “via formation hard mask pattern 22”) is formed on the deposited interlayer insulating film 21. Then, a sacrificial film 23 is formed on the via formation hard mask pattern 22.

Then, as shown in FIG. 5B, by using a hard mask pattern 24 for forming interconnects (hereinafter referred to as the “interconnect formation hard mask pattern 24”), which is made of SiO₂, the sacrificial film 23 is etched to form interconnect formation grooves 23a in the sacrificial film 23. In this step, the interconnect formation hard mask pattern 24 remains without being removed.

Then, as shown in FIG. 5C, sidewalls 25, made of SiO₂, are formed on each wall surface of the sacrificial film 23. Then, by using the interconnect formation hard mask pattern 24 and the sidewalls 25 as a mask, the interlayer insulating film 21 is etched to form a via hole 21a in the interlayer insulating film 21.

Then, as shown in FIG. 5D, conductive films 26, 27 are embedded in the via hole 21a and the interconnect formation grooves 23a. Then, the conductive films 20, 27, remaining on the interconnect formation hard mask pattern 24, are removed by a CMP method to form a via 28a and interconnects 28, which are made of the conductive films 26, 27.

Then, as shown in FIG. 5E, a porous film 29 is formed on the interconnects 28 and the interconnect formation hard mask pattern 24. Then, the sacrificial film 23 is removed by heating or the like to form voids 30. A multilayer interconnect structure is implemented by repeating the steps described above.

Moreover, Japanese Published Patent Application No. 2001-053144 as a third conventional example discloses formation of a SiO₂ film both on the sidewalls of, and on top of, interconnects having a void formed therebetween.

### SUMMARY

However, the manufacturing method of the interconnects according to the first conventional example has the following problems. That is, as shown in FIG. 6, if misalignment is caused by a lithography method when forming a via 14a which connects a first interconnect 14A to a second interconnect 14B formed in a layer located above the first interconnect 14A, the via 14a enters a void 16. Thus, the conductive films 12, 13 are embedded in the void 16. This causes conduction (a short-circuit) between the interconnects, thereby reducing the yield of semiconductor devices.

Moreover, in the manufacturing method of the interconnects according to the third conventional example, merely the SiO₂ film is formed on the sidewalls of each interconnect (the sidewalls of each void). Thus, it is difficult to prevent vias from entering the voids when the misalignment width is large and the SiO₂ film is thin.

Moreover, the first and second conventional examples have the following problems in common.

Firstly, the height of the voids 16, 30 is equal to, or smaller than that of the interconnects 14, 28. Thus, as shown in FIG. 7, lines of electric force between the interconnects 14 pass not only through the voids 16, but also through the interlayer insulating film 10 and the porous film 15. As a result, the capacitance between the interconnects does not sufficiently decrease, even through the voids 16 are formed.

Secondly, as shown in FIG. 8, no member for supporting the porous film 15 exists in a region where the gap between the interconnects 14 is relatively large. Thus, the mechanical strength decreases in this region, whereby the porous film 15 is deformed or destroyed. Thus, foreign particles enter the void 16, causing unintended conduction between the interconnects 14. This reduces the yield of semiconductor devices.

Thirdly, the porous film 15 is formed on the surfaces of the interconnects 14. Thus, as shown in FIG. 9, an oxidant, such as O₂, passes through the porous film 15, and diffuses into the interconnects 14, thereby oxidizing the interconnects 14. This increases the resistance of the interconnects 14, reducing the yield of semiconductor devices.

Note that the present invention need not necessarily solve all the problems described above, but need only solve at least one of these problems.

In view of the above conventional problems, it is an object of the present invention to prevent vias from entering voids (air gaps) and to further reduce the capacitance between interconnects, and also, to improve the mechanical strength of a multilayer interconnect structure having voids and to prevent diffusion of an oxidant, thereby enabling reduction in yield to be suppressed.

Note that the present invention need not necessarily achieve all the objects described above, but need only achieve at least one of these objects.

In order to achieve the above objects, a semiconductor device according to the present invention is configured so that a void, whose width is substantially the same as a gap between interconnects, is provided between the interconnects, an insulating film is provided so as to cover the void, and a bottom surface of the void is located lower than bottom surfaces of the interconnects.

More specifically, a semiconductor device according to the present invention includes: a first insulating film formed over a semiconductor substrate; a plurality of interconnects formed in the first insulating film, where a void is selectively formed between adjacent ones of the plurality of interconnects in the first insulating film; and a second insulating film formed in a region located over the void and between the interconnects. Respective widths of a lower end and an upper end of the void are substantially the same as a gap between the interconnects located adjacent to the void, and the lower end of the void is located lower than lower ends of the interconnects located adjacent to the void.

The semiconductor device of the present invention includes the second insulating film which is formed in the region located over the void and between the interconnects. Thus, a conductive film, which forms a via, does not enter the void even if misalignment is caused by a lithography method when forming a via hole. Moreover, since the lower end of the void is located lower than the lower ends of the interconnects located adjacent to the void, lines of electric force between the interconnects pass substantially only through the void, whereby the capacitance between the interconnects can be reduced.

In the semiconductor device of the present invention, it is preferable that a portion located under the void in the first insulating film have a lower dielectric constant than that of portions located under the interconnects in the first insulating film.

This can further reduce the capacitance between the interconnects.

In the semiconductor device of the present invention, it is preferable that, in a first gap between one interconnects, and a second gap between other interconnects in gaps between adjacent ones of the plurality of interconnects, the first gap be larger than the second gap, and no void be formed in a portion having the first gap, and the void be formed in a portion having the second gap.

In this structure, no void is formed in a region where the gap between the interconnects is relatively large. Thus, the mechanical strength of a multilayer interconnect structure is not reduced.

It is preferable that the semiconductor device of the present invention further include a third insulating film formed over the interconnects and the second insulating film, and that the third insulating film have a higher density than that of the first insulating film or the second insulating film.

This can increase the mechanical strength of an interconnect structure.

In this case, it is preferable that the third insulating film be a SiN film, a SiC film, or a SiCN film.

It is preferable that the semiconductor device of the present invention further include a cap film formed on the plurality of interconnects so as to be in contact with the interconnects.

This can prevent an oxidant from penetrating the interconnects from the upper side of the interconnects.

In this case, it is preferable that the cap film be made of Co, Mn, W, Ta, or Ru, or an alloy containing at least one kind of a metal selected from Co, Mn, W, Ta, and Ru, or an oxide of Co, Mn, W, Ta, or Ru, or CuSiN, and that the cap film have a conductive property.

A method for manufacturing a semiconductor device according to the present invention includes the steps of: (a) forming a first insulating film over a semiconductor substrate; (b) forming a plurality of interconnect formation grooves in the first insulating film; (c) embedding a conductive film in the interconnect formation grooves to form a plurality of interconnects; (d) selectively forming a void formation groove between the interconnects in the first interlayer insulating film; (e) forming a sacrificial film in the void formation groove; (f) removing an upper part of the sacrificial film to form a recess in the upper part of the sacrificial film; (g) forming a second insulating film in the recess; and (h) after the step (g), removing the sacrificial film from the void formation groove to form a void between the interconnects in the first insulating film.

According to the manufacturing method of the semiconductor device of the present invention, the sacrificial film is formed in the void formation groove, and the upper part of the formed sacrificial film is removed to form the recess in the upper part of the sacrificial film. Next, the second insulating film is formed in the recess, and then, the sacrificial film is removed from the void formation groove to form the void between the interconnects in the first insulating film. Thus, since the void is covered by the second insulating film, a conductive film, which form a via, does not enter the void even if misalignment is caused by a lithography method when forming a via hole.

In the method of the present invention, it is preferable that, in the step (d), the void formation groove be formed so that a lower end of the void formation groove is located lower than lower ends of the interconnects.

In this case, lines of electric force between the interconnects pass substantially only through the void, whereby the capacitance between the interconnects can be reduced.

According to the method of the present invention, it is preferable that, in the step (h), a dielectric constant of a portion located under the void formation groove in the first insulating film be made smaller than that of portions located under the interconnects in the first insulating film.

This can further reduce the capacitance between the interconnects.

In the method of the present invention, it is preferable that, in the step (d), in a portion having a first gap between one interconnects, and a portion having a second gap between other interconnects in gaps between adjacent ones of the plurality of interconnects, the first gap be made larger than the second gap, and no void formation groove be formed in the portion having the first gap, and the void formation groove be formed in the portion having the second gap.

In this case, no void is formed in a region where the gap between the interconnects is relatively large. Thus, the mechanical strength of a multilayer interconnect structure is not reduced.

It is preferable that the method of the present invention further include the step of (i) after the step (h), forming a third insulating film over the interconnects and the second insulating film.

In the method of the present invention, it is preferable that, in the step (i), the third insulating film be formed so as to have a higher density than that of the first insulating film or the second insulating film.

This can increase the mechanical strength of an interconnect structure.

In these cases, it is preferable that the third insulating film be a SiN film, a SiC film, or a SiCN film.

It is preferable that the method of the present invention further include the step of: (j) between the steps (c) and (d), forming a cap film on the plurality of interconnects so that the cap film is in contact with the interconnects.

This can prevent an oxidant from penetrating the interconnects from the upper side of the interconnects.

In this case, it is preferable that the cap film be made of Co, Mn, W, Ta, or Ru, or an alloy containing at least one kind of a metal selected from Co, Mn, W, Ta, and Ru, or an oxide of Co, Mn, W, Ta, or Ru, or CuSiN, and that the cap film have a conductive property.

In the semiconductor device and the manufacturing method thereof according to the present invention, vias can be prevented from entering voids, and the capacitance between interconnects can be reduced. Moreover, the mechanical strength of a multilayer interconnect structure can be improved, and diffusion of an oxidant into interconnects can be suppressed, whereby the yield of semiconductor devices can be improved.

### BRIEF DESCRIPTION OF THE DRAWINGS

FIG. 1 is a cross-sectional view showing a main part of a semiconductor device according to an example embodiment.

FIGS. 2A, 2B, 2C, 2D, and 2E are step-by-step cross-sectional views illustrating a manufacturing method of a main part of the semiconductor device according to the example embodiment.

FIGS. 3A, 3B, 3C, and 3D are step-by-step cross-sectional views illustrating the manufacturing method of the main part of the semiconductor device according to the example embodiment.

FIGS. 4A, 4B, 4C, 4D, and 4E are step-by-step cross-sectional views illustrating a manufacturing method of a semiconductor device according to a first conventional example.

FIGS. 5A, 5B, 5C, 5D, and 5E are step-by-step cross-sectional views illustrating a manufacturing method of a semiconductor device according to a second conventional example.

FIG. 6 is a cross-sectional view illustrating problems in the first conventional example.

FIG. 7 is a cross-sectional view illustrating a first problem which is common to the first and second conventional examples.

FIG. 8 is a cross-sectional view illustrating a second problem which is common to the first and second conventional examples.

FIG. 9 is a cross-sectional view illustrating a third problem which is common to the first and second conventional examples.

### DETAILED DESCRIPTION

### Example Embodiment

An example embodiment will be described with reference to the accompanying drawings.

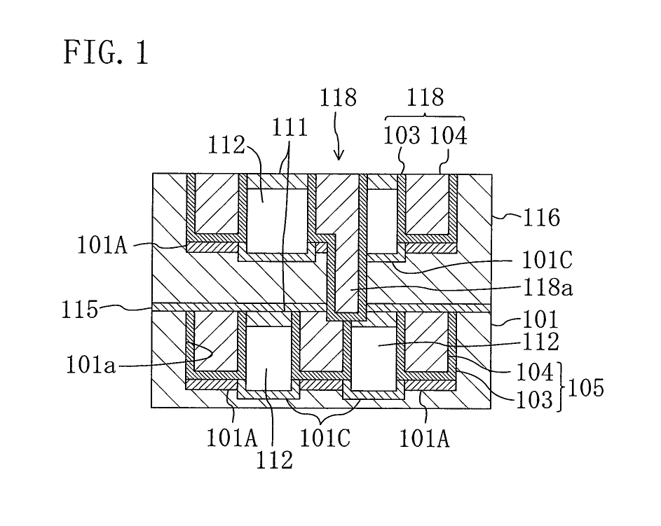

FIG. 1 shows a main part of a semiconductor device according to an example embodiment, showing a cross-sectional structure of a multilayer interconnect structure.

As shown in FIG. 1, a first interlayer insulating film 101, made of, for example, SiOC, is formed with a thickness of about 200 nm on a semiconductor substrate (not shown). In the first interlayer insulating film 101, a barrier film 103 is formed on the bottom and wall surfaces of first grooves 101a for forming interconnects (hereinafter referred to as the “first interconnect formation grooves 101a”), a copper film 104 is embedded inside the barrier film 103, and first interconnects 105 are formed by the barrier film 103 and the copper film 104. A laminated film, formed by sequentially depositing tantalum (Ta) and tantalum nitride (TaN) in this order, is herein used as the barrier film 103.

A void (an air gap) 112 is formed between the first interconnects 105. The respective widths of a lower end and an upper end of each void 112 are about the same as the gap between the first interconnects 105. That is, opposing side surfaces of the first interconnects 105, which have the void 112 provided therebetween, are exposed. The height of each void 112 is herein about 140 nm.

A cap insulating film 111 is formed on the voids 112 so as to close the voids 112. The cap insulating film 111 is made of, for example, SiOC, and has a thickness of about 50 nm.

A liner film 115, made of, for example, SiCN, is formed with a thickness of about 60 nm over the whole surface of the first interlayer insulating film 101, including the first interconnects 105 and the cap insulating film 111.

A second interlayer insulating film 116, made of SiOC, is formed with a thickness of about 200 nm on the liner film 115. Like the first interconnects 105, second interconnects 118, made of a barrier film 103 and a copper film 104, are formed in the second interlayer insulating film 116. Vias 118a, which are electrically connected to the first interconnects 105, are selectively formed in the second interconnects 118. As a feature of the present disclosure, the vias 118a extend through the liner film 115, but do not extend through the cap insulating film 111.

Moreover, a first damage layer 101A is formed in the portions which are located under the first interconnects 105 in the first interlayer insulating film 101, and in the portions which are located under the second interconnects 118 in the second interlayer insulating film 116. The first damage layer 101A herein refers to an insulating film having a higher dielectric constant than that of SiOC which forms the first interlayer insulating film 101 and the second interlayer insulating film 116. The first damage layer 101A is formed by, for example, a dry etching process which is performed to form the first interconnect formation grooves 101a in the first interlayer insulating film 101.

On the other hand, a modified layer 101C is formed in the portions which are located under the voids 112 in the first interlayer insulating film 101, and in the portions which are located under the voids 112 in the second interlayer insulating film 116. The modified layer 101C herein refers to an insulating film having a lower dielectric constant, or higher mechanical strength, than that of the first damage layer 101A and a second damage layer 101B described below.

Note that the materials, thicknesses, and height dimensions of various insulating films and conductive films used in this example embodiment are not limited to those described above.

According to the semiconductor of this example embodiment, for example, the cap insulating film 111, whose width is about the same as the gap between the interconnects 105, is formed on the voids 112 which are selectively formed between adjacent ones of the plurality of first interconnects 105 formed in the first interlayer insulating film 101, so as to close the voids 112. Thus, even if misalignment occurs when forming the vias 118a, which are connected to the second interconnects 118, over the first interconnects 105, the vias 118a can be prevented from entering the voids 112 located thereunder.

The thickness of the cap insulating film 111 will be described in detail below.

In order to prevent the vias 118a from entering the voids 112 by forming the cap insulating film 111 which closes the voids 111, the cap insulating film 111 needs to have an appropriate thickness. On the other hand, since the cap insulating film 111 itself has a higher dielectric constant than that of air, the thickness of the cap insulating film 111 needs to be reduced as much as possible in order to reduce the effective dielectric constant between the interconnects. Thus, it is necessary to examine the relation between the thickness of the cap insulating film 111 and the effective dielectric constant.

In this example embodiment, a SiOC film, having a relative dielectric constant of about 3.0, and a thickness of about 200 nm, is deposited as the first interlayer insulating film 101, and in order to form the voids 112, an etching process is performed until the SiOC film of about 10 nm thickness is left. Moreover, a SiOC film, having a relative dielectric constant of about 3.0, is used as the cap insulating film 111, and the thickness of the cap insulating film 111 is adjusted to about 50 nm. As a result, the height of the voids 112 becomes about 140 nm.

By forming the cap insulating film 111 with the type and thickness described above, the effective dielectric constant between the interconnects becomes about 1.6. However, the thickness of the cap insulating film 111 and the effective dielectric constant between the interconnects are not limited to the values described above. For example, the thickness of the cap insulating film 111 and the effective dielectric constant between the interconnects needs to be adjusted as appropriate in view of the effectiveness of the cap insulating film 111 and the effectiveness of the dielectric constant between the interconnects.

A method for calculating the effective dielectric constant is shown below.

Effective dielectric constant=SiOC film thickness (about 10 nm)/total film thickness (about 200 nm)×relative dielectric constant of SiOC (about 3.0)

+void height (about 140 nm)/total film thickness (about 200 nm)×relative dielectric constant of the void (about 1.0)

+SiOC film thickness (about 50 nm)/total film thickness (about 200 nm)×relative dielectric constant of SiOC (about 3.0)

Although the SiOC film is herein used as the cap insulating film 111, the cap insulating film 111 is not limited to this. That is, the cap insulating film 111 may be any insulating film which is porous enough to allow decomposed components of the sacrificial film to pass therethrough.

Moreover, according to the semiconductor device of this example embodiment, the voids 112 are formed so that the lower ends of the voids 112 are positioned lower than, for example, the lower ends of the first interconnects 105 located adjacent to the voids 112. This can sufficiently reduce the dielectric constant between the interconnects, as compared to the above conventional examples in which the voids are only formed, or can only be formed, so that the lower ends of the voids are positioned at the same height as, or higher than, the lower ends of the interconnects located adjacent to the voids.

Moreover, according to the semiconductor device of this example embodiment, the modified layer 101C, which is formed, for example, in the portions located under the voids 112 (i.e., at the bottoms of the voids 112) in the first interlayer insulating film 101, has a lower dielectric constant than that of the first damage layer 101A, which is formed in the portions located under the first interconnects 105. Thus, the dielectric constant between the interconnects can be sufficiently reduced as compared to the above conventional examples.

Moreover, according to the semiconductor device of this example embodiment, the voids 112 are formed only in a region where the gap between the interconnects is relatively small. That is, no void 112 is formed in a region where the gap between the interconnects is relatively large. More specifically, the semiconductor device of this example embodiment is characterized in that, in a first gap between one interconnects and a second gap between other interconnects in the gaps between adjacent ones of a plurality of interconnects, the first gap is larger than the second gap, and no void 112 is formed in the first gap, and the voids 112 are formed in the second gap. It is preferable that the first gap be a gap whose length is more than three times the smallest distance between the interconnects in the same interconnect layer, and that the second gap be a gap whose length is at least equal to the smallest distance between the interconnects in the same interconnect layer, and at most three times the smallest distance between the interconnects in the same interconnect layer. Since the cap interlayer insulating film 111 is formed on top of the voids 112, the mechanical strength is increased. As a result, forming the voids 112 causes no mechanical problem if the gap between the interconnects is at most three times the smallest distance between the interconnects. It should be noted that the first gap and the second gap are not limited to the above ranges if the mechanical strength is maintained. Thus, the mechanical strength of the interconnect structure can be increased as compared to the conventional examples in which the voids are not, or cannot be, selectively formed.

Moreover, according to the semiconductor device of this example embodiment, no porous film is used as the liner film 115. That is, SiCN, which has a higher density than that of SiOC used as a material of the first interlayer insulating film 101, is used as the liner film 115. Note that, although SiCN is used as the liner film 115 in this example embodiment, the liner film 115 is not limited to SiCN, and for example, SiC, SiN, or the like may be used. Thus, since no porous film is used as the liner film 115, the first interconnects 105 are not oxidized by an oxidant after the liner 115 is formed. A conductive cap film may be formed on top of the first interconnects 105 and the second interconnects 118 so as to be in contact with the interconnects 105, 118. Providing the conductive cap film on top of the interconnects 105, 118 makes the interconnects 105, 118 less likely to be oxidized by an oxidant, as compared to the case where no such cap film is formed.

Note that, in the case of forming the conductive cap film on top of the interconnects 105, 118, a porous film may be used as the liner film 115. The use of the porous film as the liner film 115 can further reduce the dielectric constant between the interconnects. It is preferable that the cap film be made of cobalt (Co), manganese (Mn), tungsten (W), tantalum (Ta), or ruthenium (Ru), or an alloy containing at least one kind of a metal selected from Co, Mn, W, Ta, and Ru, or an oxide of Co, Mn, W, Ta, or Ru, or copper-added silicon nitride (CuSiN), and that the cap film have a conductive property.

A manufacturing method of the semiconductor device structured as described above will be described below with reference to the drawings.

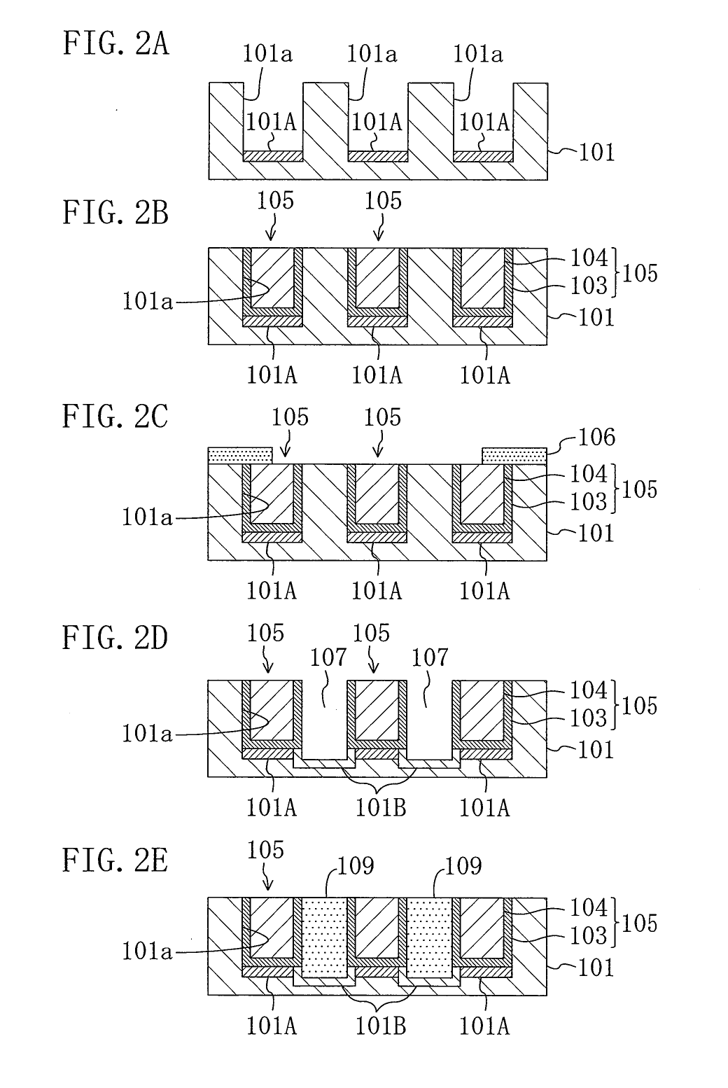

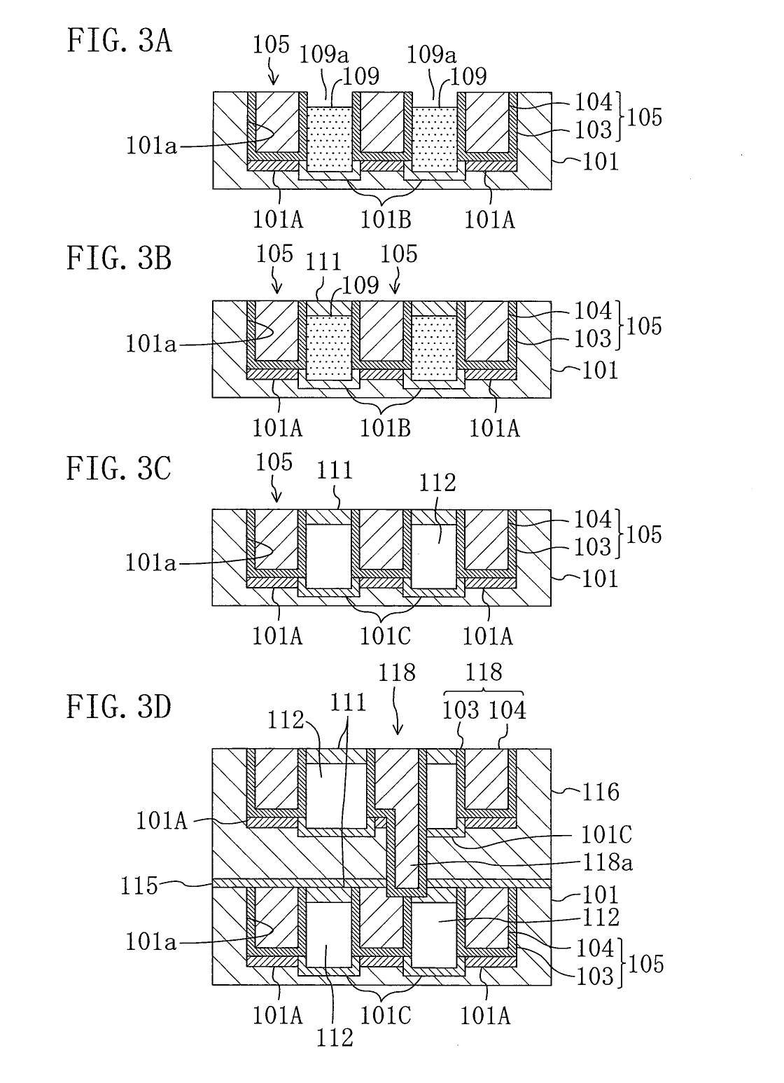

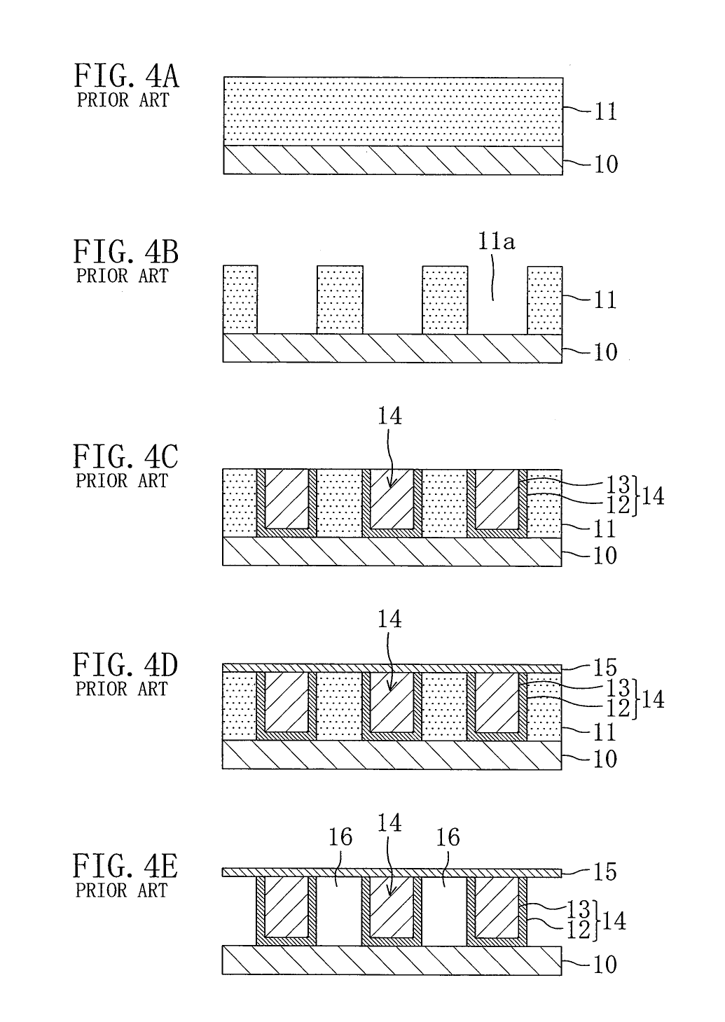

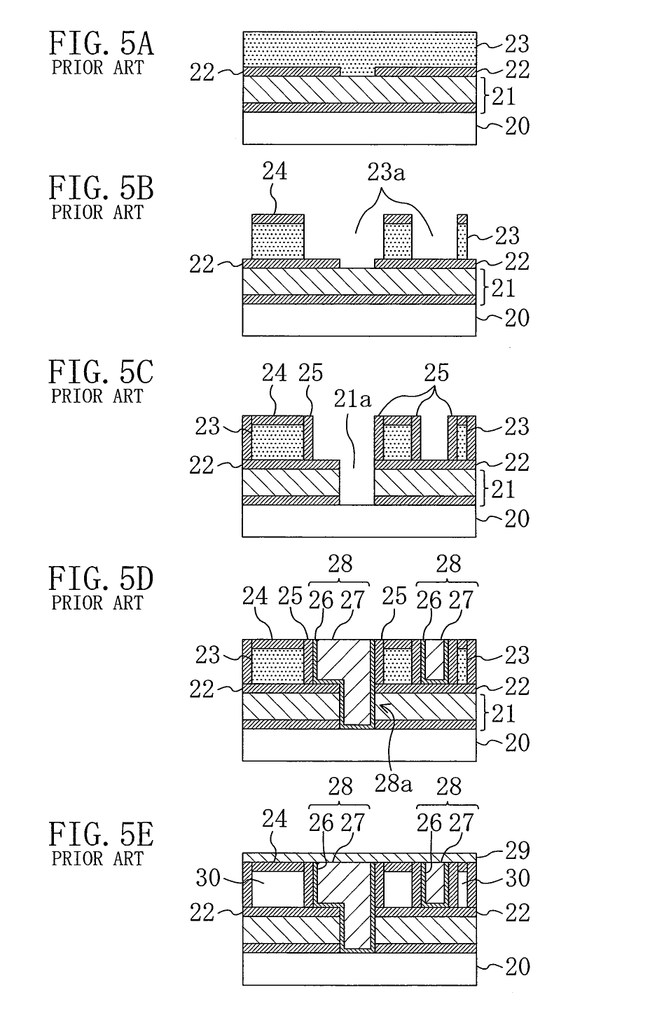

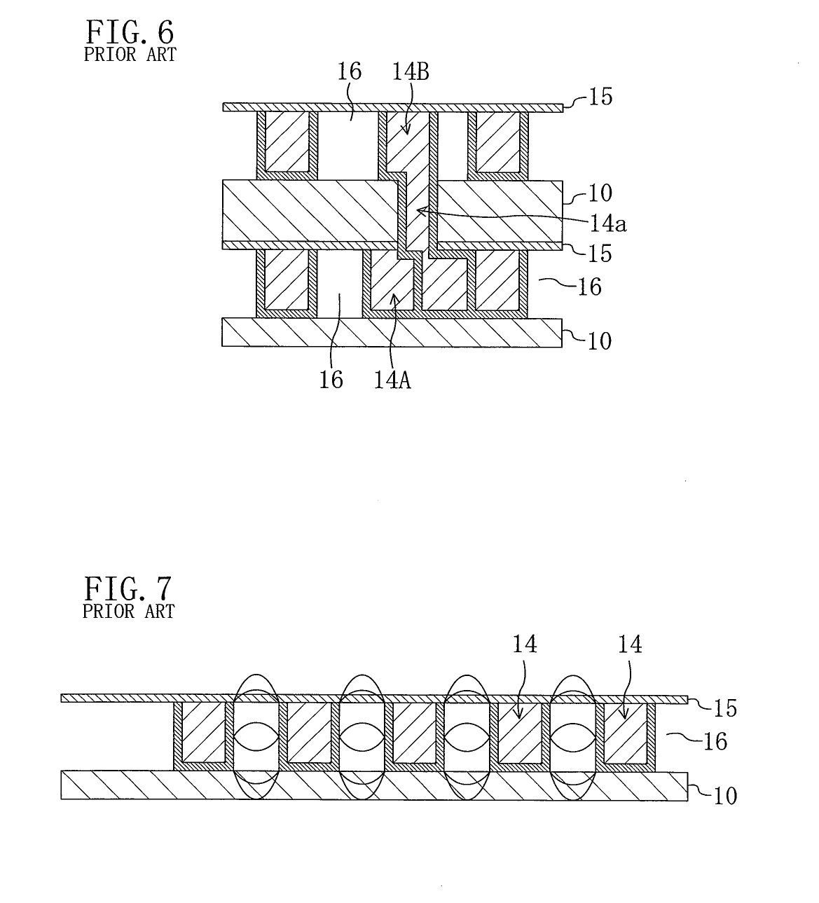

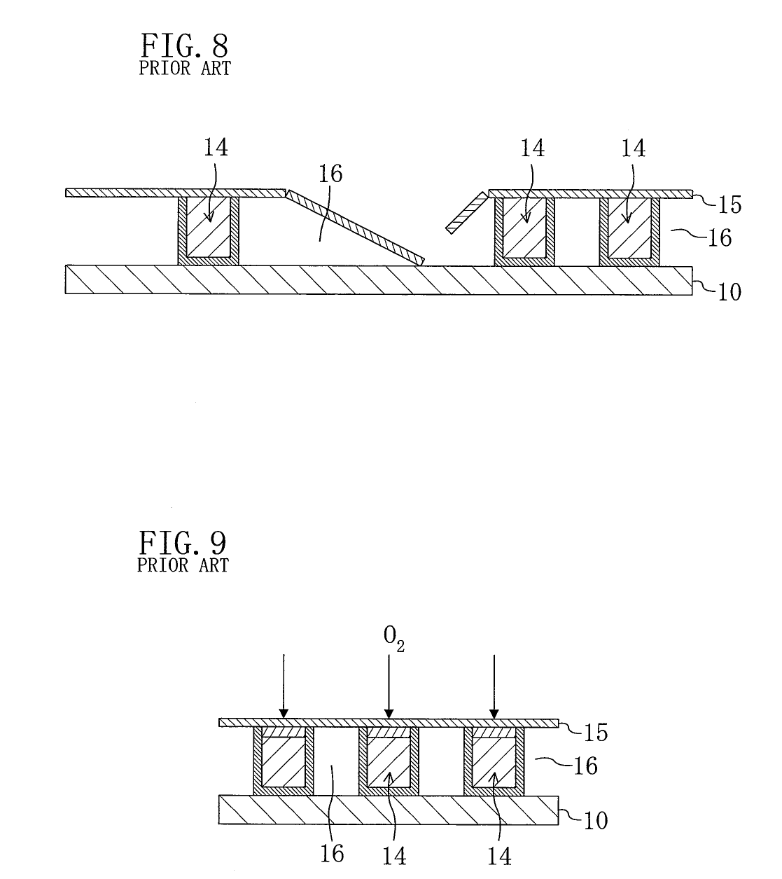

FIGS. 2A through 2E and FIGS. 3A through 3D show step-by-step cross-sectional structures of a main part of the manufacturing method of the semiconductor device according to the example embodiment.

First, as shown in FIG. 2A, a first interlayer insulating film 101, made of SiOC, is deposited with a thickness of about 200 nm by, for example, a chemical vapor deposition (CVD) method on a silicon (Si) semiconductor substrate (not shown) on which a plurality of semiconductor elements have been formed. Then, a plurality of interconnect formation grooves 101a are formed spaced apart from each other in the first interlayer insulating film 101 by a lithography method and a dry etching method. At this time, a first damage layer 101A, having a relatively high dielectric constant, that is, having a dielectric constant higher than at least that of SiOC, is formed by a dry etching method at the bottoms of the first interconnect formation grooves 101a in the first interlayer insulating film 101.

Then, as shown in FIG. 2B, a barrier film 103, made of tantalum (Ta)/tantalum nitride (TaN), and a copper film 104 are sequentially deposited over the whole surface of the first interlayer insulating film 101, including the first interconnect formation grooves 101a, by a sputtering method and a plating method. Then, an unwanted barrier film 103 and an unwanted copper film 104, which are deposited on a region other than the first interconnect formation grooves 101a on the first interlayer insulating film 101, are removed by a chemical mechanical polishing (CMP) method to form first interconnects 105, which are formed by the barrier film 103 and the copper film 104, in the first interconnect formation grooves 101a. Note that, although a laminated film of the Ta film and the TaN film is used as the barrier film 103 in this example embodiment, one of the Ta film and the TaN film may be used as the barrier film 103. Moreover, although copper (Cu) is used as a conductive film which is embedded in the first interconnect formation grooves 101a, the conductive film is not limited to copper. Silver (Ag) or aluminum (Al), or an alloy thereof, or the like may be used as the conductive film.

Then, as shown in FIG. 2C, a resist pattern 106, having an opening pattern for selectively opening the first interlayer insulating film 101 between at least two of the plurality of first interconnects 105, is formed over the first interlayer insulating film 101 by a lithography method.

Then, as shown in FIG. 2D, by using the resist pattern 106 as a mask, a part of the first interlayer insulating film 101 is removed by a dry etching method using a carbon fluoride (CF)-based gas, thereby forming grooves 107 for forming voids (hereinafter referred to as the “void formation grooves 107”). At this time, the dry etching conditions are set so that the height of the bottom surfaces of the void formation grooves 107 from the substrate surface becomes lower than that of the bottom surfaces of the first interconnects 105 from the substrate surface. Note that since a fluoride has a low vapor pressure, the barrier film 103 and the copper film 104 are left without being etched. Moreover, as a side effect of this etching process, Si—CH₃ bonds included in the first interlayer insulating film 101 are partially replaced with Si—OH bonds, and thus, a second damage layer 101B, having a relatively high dielectric constant, that is, having a dielectric constant higher than at least that of SiOC, is formed on the bottom surfaces and the lower parts of the wall surfaces of the void formation grooves 107 in the first interlayer insulating film 101.

Then, as shown in FIG. 2E, a sacrificial film 109, made of a polymer, is applied to the whole surface of the first interlayer insulating film 101, including the first interconnects 105 and the void formation grooves 107. Then, the sacrificial film 109, which is formed in a region except for the void formation grooves 107 on the first interlayer insulating film 101, is removed by a CMP method to embed the sacrificial film 109 in the void formation grooves 107. Note that preferred characteristics (physical properties) and a preferred material of the sacrificial film 109 will be described later.

Then, as shown in FIG. 3A, an upper part of the sacrificial film 109 is removed by a dry etching method to form recesses 109a on the sacrificial film 109 in the first interlayer insulating film 101.

Then, as shown in FIG. 3B, a porous cap insulating film 111, made of SiOC, is deposited with a thickness of about 50 nm on the first interlayer insulating film 101 and the first interconnects 105 so as to embed the recesses 109a. Then, an unwanted cap insulating film 111, remaining on the first interlayer insulating film 101 and the first interconnects 105, is removed by a CMP method.

Then, as shown in FIG. 3C, the semiconductor substrate is heated to thermally decompose the sacrificial film 109 embedded in the void formation grooves 107, thereby forming voids 112, having a height of about 140 nm, between the first interconnects 105 located adjacent to the sacrificial film 109. When the sacrificial film 109 is thermally decomposed, Si—OH bonds, which are included in the second damage layer 101B formed under the sacrificial film 109, are partially replaced with Si—CH₃ bonds. As a result, the second damage layer 101B changes to a modified layer 101C. Note that the phenomenon in which the second damage layer 101B changes to the modified layer 101C will be described in detail later. Moreover, a part of a decomposition product of the sacrificial film 109 diffuses through the porous first interlayer insulating film 101 and the porous cap insulating film 111, and is discharged to the outside.

Then, by, for example, a CVD method, a liner film 115, made of SiCN, is formed with a thickness of about 60 nm over the whole surface of the first interlayer insulating film 101, including the cap insulating film 111 and the first interconnects 105. Then, a second interlayer insulating film 116, made of SiOC, is formed with a thickness of about 200 nm on the liner film 115. Then, via holes 118a connecting to the first interconnects 105 are formed in the second interlayer insulating film 116 by a lithography method and a dry etching method.

A two-layer interconnect structure shown in FIG. 3D is formed by repeating the steps of FIGS. 2C through 2E and FIGS. 3A through 3C thereafter, and a multilayer interconnect structure is formed by further repeating the steps described above.

This example embodiment was described with respect to a method (a dual damascene method) for forming vias 118a and second interconnects 118 by first forming via holes, then forming second interconnect formation grooves, and embedding a conductive film in the formed second interconnect formation grooves. However, the vias 118a may first be formed by forming via holes, and embedding a conductive film therein, and the second interconnects 118 may then be formed by forming interconnect formation grooves, and embedding a conductive film therein. Alternatively, the vias 118a and the second interconnects 118 may be formed simultaneously by first forming interconnect formation, then forming via holes, and embedding a conductive film therein.

Note that the process conditions described in the above manufacturing method of the semiconductor device are presented by way of example only, and the present disclosure is not limited to them.

In some cases, for example, formation of the damage layers 101A, 101B in the dry etching steps shown in FIGS. 2A and 2D can be prevented by optimizing the dry etching conditions. In such cases, it is not necessary to use a crosslinkable polymer, having a functional group represented by chemical formula (1) or (2) below, as a material of the sacrificial film 109. In addition, the present disclosure can be embodied in various forms without departing from the sprit and scope of the present disclosure.

As described above, the manufacturing method of the semiconductor device of this example embodiment can provide the following effects in addition to the effects similar to those of the semiconductor device of this example embodiment.

First, no porous film is used as the liner film 115 which covers the upper surfaces of the first interconnects 105. This prevents the first interconnects 105 from being oxidized by an oxidant after the liner film 115 is formed. As described above, a conductive cap film may be formed on top of each interconnect 105, 118 so as to be in contact with the interconnects 105, 118. In the case where the conductive cap film is provided, oxidation of the interconnects 105, 118 by an oxidant is less likely to occur, as compared to the case where no cap film is provided.

Moreover, in the case where a conductive cap film is provided, a porous film may be used as the liner film 115. The use of a porous film can further reduce the dielectric constant between the interconnects.

Note that, according to the manufacturing method of the semiconductor device of this example embodiment, the via holes need to be formed so as to extend through the liner film 115 formed on the cap insulating film 111. On the other hand, however, the via holes need to be prevented from extending through the cap insulating film 111. Thus, the thickness ratio of the liner film 115 to the cap insulating film 111 needs to be controlled to an appropriate value. In this example embodiment, a SiOC film having a thickness of about 50 nm is formed as the cap insulating film 111.

Moreover, a SiCN film, having a thickness of about 60 nm, is formed as the liner film 115 which is formed on the cap insulating film 111 made of SiOC. In this case, when forming the via holes by a dry etching method, the etching selectivity can be set to SiCN:SiOC=2:1 by using a CF-based gas and an N₂ gas. That is, the etching selectivity can be adjusted so that the SiOC film is not significantly removed as compared to the SiCN film. On the other hand, the amount of overetching by the dry etching process corresponds to 20% of the thickness of the liner film 115 formed on the cap insulating film 111. Thus, when forming the vias 118a in this example embodiment, the cap insulating film 111 is etched away only by about 6 nm, which is one half of about 12 nm. In this case, since the thickness of the cap insulating film 111 is about 50 nm, a laminated structure, through which neither the via holes nor the voids 112 extend, can be formed.

Moreover, the SiOC film used as the cap insulating film 111, and the SiCN film used as the liner film 115 are generally highly adhesive to each other. Thus, the cap insulating film 111 and the liner film 115 hardly peel off from the interface therebetween.

The effect of changing the second damage layer 102B, which is formed in the portions located under the sacrificial film 109 in the first insulating film 101, that is, which is formed at the bottoms of the voids 112, into the modified layer 101C will be described below. As described above, in the second damage layer 101B formed in the portions located under the sacrificial film 109, Si—CH₃ bonds included in SiOC have been partially replaced with Si—OH bonds. Thus, the second damage layer 101B has an intermediate property between SiOC and SiO₂, and has a higher dielectric constant than that of SiOC. Thus, leaving the second damage layer 101B at the bottoms of the voids 112 causes a problem of increasing the capacitance between the interconnects. Thus, it is preferable to suppress the capacitance between the first interconnects 105 to a low value by replacing the Si—OH bonds included in the second damage layer 101B back with Si—CH₃ bonds, and thus changing the second damage layer 101B to the modified layer 101C having closer characteristics to those of SiOC, as in the example described above.

Characteristics required for the sacrificial film 109, and a preferred material thereof will be described below. As can be seen from the above description, the following two characteristics are required for the sacrificial film 109. Firstly, the sacrificial film 109 can be decomposed by heating to form the voids 112. Secondly, a decomposition product of the sacrificial film 109 can change the second damage layer 101B to the modified layer 101C.

Thus, it is preferable to use a crosslinkable polymer, having a functional group represented by the chemical formula (1) or (2), as a material of the sacrificial film 109. Note that an example of the chemical formula (1) or (2) includes hexamethyldisilazane {(CH₃)₃Si—NH—Si(CH₃)₃}, or the like.

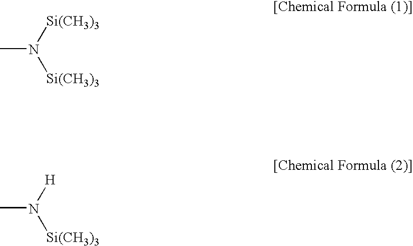

It is known that a crosslinkable polymer, which is appropriately structurally designed, is decomposed at a temperature of 300° C. to 400° C. However, the thermal decomposition temperature is not limited to this range. Moreover, adding a functional group represented by the chemical formula (1) or (2) generates a substance, represented by the following chemical formula (3) or (4), by thermal decomposition.

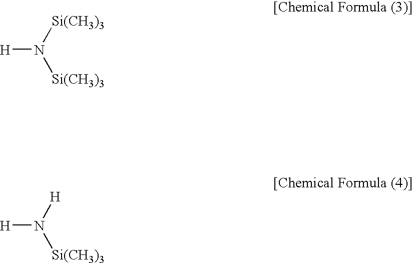

This is because a substance having the structure represented by the chemical formula (3) has a function to replace a Si—OH group with a Si—CH₃ group by the reaction represented by a chemical formula (5) below, and a substance having the structure represented by the chemical formula (4) has a function to replace a Si—OH group with a Si—CH₃ group by the reaction represented by the following chemical formula (6).

(CH₃)₃Si—NH—Si(CH₃)_{3(g)}+HO—Si≡₍ₛ₎→(CH₃)₃—Si—O—Si≡₍ₛ₎+(CH₃)₃—SiNH_{2(g)} [Chemical Formula (5)]

(CH₃)₃—SiNH_{2(g)}+HO—Si≡₍ₛ₎→(CH₃)₃—Si—O—Si≡₍ₛ₎+NH_{3(g)} [Chemical Formula (6)]

Thus, a crosslinkable polymer, having a functional group represented by the chemical formula (1) or (2), is preferably used as the sacrificial film 109. However, the sacrificial film 109 is not limited to the crosslinkable polymer having a functional group represented by the chemical formula (1) or (2).

Note that “(s)” added to the chemical formulas (5) and (6) represents a solid phase, and “(g)” represents a gas phase.

The semiconductor device and the manufacturing method thereof according to the present disclosure are capable of preventing vias from entering voids, and reducing the capacitance between interconnects. Moreover, the semiconductor device and the manufacturing method thereof according to the present disclosure are capable of improving the mechanical strength of a multilayer interconnect structure, and of suppressing diffusion of an oxidant into interconnects, and are especially useful for a semiconductor device having a multilayer interconnect structure, and a manufacturing method thereof, and the like.

What is claimed is:

1. A semiconductor device, comprising:
a first insulating film formed over a semiconductor substrate;
a plurality of interconnects formed in the first insulating film, where a void is selectively formed between adjacent ones of the plurality of interconnects in the first insulating film; and
a second insulating film formed in a region located over the void and between the interconnects, wherein
respective widths of a lower end and an upper end of the void are substantially the same as a gap between the interconnects located adjacent to the void, and
the lower end of the void is located lower than lower ends of the interconnects located adjacent to the void.

2. The semiconductor device of claim 1, wherein
a portion located under the void in the first insulating film has a lower dielectric constant than that of portions located under the interconnects in the first insulating film.

3. The semiconductor device of claim 1, wherein
in a first gap between one interconnects, and a second gap between other interconnects in gaps between adjacent ones of the plurality of interconnects, the first gap is larger than the second gap, and no void is formed in a portion having the first gap, and the void is formed in a portion having the second gap.

4. The semiconductor device of claim 1, further comprising:
a third insulating film formed over the interconnects and the second insulating film, wherein
the third insulating film has a higher density than that of the first insulating film or the second insulating film.

5. The semiconductor device of claim 4, wherein
the third insulating film is a SiN film, a SiC film, or a SiCN film.

6. The semiconductor device of claim 1, further comprising:
a cap film formed on the plurality of interconnects so as to be in contact with the interconnects.

7. The semiconductor device of claim 6, wherein
the cap film is made of Co, Mn, W, Ta, or Ru, or an alloy containing at least one kind of a metal selected from Co, Mn, W, Ta, and Ru, or an oxide of Co, Mn, W, Ta, or Ru, or CuSiN, and
the cap film has a conductive property.

8. A method for manufacturing a semiconductor device, comprising the steps of:
(a) forming a first insulating film over a semiconductor substrate;
(b) forming a plurality of interconnect formation grooves in the first insulating film;
(c) embedding a conductive film in the interconnect formation grooves to form a plurality of interconnects;
(d) selectively forming a void formation groove between the interconnects in the first interlayer insulating film;
(e) forming a sacrificial film in the void formation groove;
(f) removing an upper part of the sacrificial film to form a recess in the upper part of the sacrificial film;
(g) forming a second insulating film in the recess; and
(h) after the step (g), removing the sacrificial film from the void formation groove to form a void between the interconnects in the first insulating film.

9. The method of claim 8, wherein
in the step (d), the void formation groove is formed so that a lower end of the void formation groove is located lower than lower ends of the interconnects.

10. The method of claim 8, wherein
in the step (h), a dielectric constant of a portion located under the void formation groove in the first insulating film is made smaller than that of portions located under the interconnects in the first insulating film.

11. The method of claim 8, wherein
in the step (d), in a portion having a first gap between one interconnects, and a portion having a second gap between other interconnects in gaps between adjacent ones of the plurality of interconnects, the first gap is made larger than the second gap, and no void formation groove is formed in the portion having the first gap, and the void formation groove is formed in the portion having the second gap.

12. The method of claim 8, further comprising the step of:
(i) after the step (h), forming a third insulating film over the interconnects and the second insulating film.

13. The method of claim 12, wherein
in the step (i), the third insulating film is formed so as to have a higher density than that of the first insulating film or the second insulating film.

14. The method of claim 12, wherein
the third insulating film is a SiN film, a SiC film, or a SiCN film.

15. The method of claim 8, further comprising the step of:
(j) between the steps (c) and (d), forming a cap film on the plurality of interconnects so that the cap film is in contact with the interconnects.

16. The method of claim 15, wherein
the cap film is made of Co, Mn, W, Ta, or Ru, or an alloy containing at least one kind of a metal selected from Co, Mn, W, Ta, and Ru, or an oxide of Co, Mn, W, Ta, or Ru, or CuSiN, and
the cap film has a conductive property.
